(19) United States
(12) Patent Application Publication
(10) Pub. No.: US 2011/0053374 A1
(43) Pub. Date: Mar. 3, 2011

(54) METHOD FOR MANUFACTURING SEMICONDUCTOR DEVICE

(75) Inventor: Motoshige Kobayashi, Hyogo-ken (JP)

(73) Assignee: KABUSHIKI KAISHA TOSHIBA, Tokyo (JP)

(21) Appl. No.: 12/719,949

(22) Filed: Mar. 9, 2010

(30) Foreign Application Priority Data
Aug. 25, 2009 (JP) 2009-194842

(51) Int. Cl. H01L 21/3205

(52) U.S. Cl. 438/674; 257/E21.295

(57) ABSTRACT

There is provided a method for manufacturing a semiconductor device which is capable of stably forming a plated layer on a plating base layer while adhered chippings are reduced. The method includes forming an insulating film covering at least a base metal on a diffusion region of a semiconductor substrate, forming an organic coating film having an opening at least at a surface section of the base metal being to be exposed on the insulating film, pasting a surface protection tape on the semiconductor substrate to cover the insulating film and the organic coating film, polishing a back surface of the semiconductor substrate that opposes the base metal, removing the surface protection tape, etching the insulating film with the organic coating film used as a mask to expose the base metal and forming a conductive plated layer on the base metal.

### CROSS-REFERENCE TO RELATED APPLICATION

This application is based upon and claims the benefit of priority from the prior Japanese Patent Application No. 2009-194842, filed on Aug. 25, 2009, the entire contents of which are incorporated herein by reference.

### FIELD

The disclosure relates generally to a method for manufacturing a semiconductor device.

### BACKGROUND

In a semiconductor device, a back surface of a semiconductor substrate, on which no semiconductor element is formed, is often polished in a final step or in a step close to the final step during manufacturing process in order to make the semiconductor substrate thinner. In the polishing step, chippings are made from the semiconductor substrate. In some cases, even after cleaning, the chippings may remain on electrodes (wiring layer, pads, and the like) that are exposed to the surface side and are connected to the semiconductor element. The chippings may exert various adverse effects on the steps after the polishing step.

In order to avoid such adverse effects, for example, JP-A 2004-71792 (KOKAI) discloses a method for manufacturing a semiconductor device. This method includes steps of applying a photosensitive polyimide film on a pad electrode, polishing a back surface of a semiconductor substrate in a state where the semiconductor substrate is exposed to light for patterning. And this method includes steps of developing and removing the photosensitive polyimide film on the pad electrode after the back surface of the semiconductor substrate is polished, and causing the pad electrode to be exposed.

In the method for manufacturing the semiconductor device, the back surface can be polished without remaining chippings to the pad electrode on the surface side. However, it is necessary to arrange the step for developing (patterning) the photosensitive polyimide film on the surface of the thin semiconductor substrate. The thin semiconductor substrate is different from a thick semiconductor substrate. A dedicated jig or device is necessary to handle the thin semiconductor substrate. In addition, there is a problem in that it takes much time to complete the process due to the required more careful handling. Further, it is difficult to maintain the yield of the production.

It should be noted that the disclosed method for manufacturing a semiconductor device does not use a surface protection tape (film). Therefore, it is necessary to arrange a rather thick photosensitive polyimide film in order to ensure a surface protection function possessed by the surface protection tape. As a result, the film thickness of the protection film needed in the semiconductor device does not necessarily be the same as the film thickness of the surface protection film-substitute needed in the polishing step. And it may be necessary to adjust the film thickness of the photosensitive polyimide film after development. Further, a method for stacking a conductive plated layer on a base metal (corresponding to the pad electrode, the wiring metal, and the like) is not described in the disclosed method for manufacturing a semiconductor device.

Further, the disclosed method for manufacturing a semiconductor device is limited to the photosensitive polyimide film. Therefore, there is a drawback in that the disclosed method cannot be applied to a non-photosensitive polyimide film having excellent adhesiveness and chemical resistance.

Moreover, the disclosed method for manufacturing a semiconductor device includes the steps of exposure to light, polishing of the back surface, and development. However, it is necessary to perform the steps in an environment in which there is no light having a wavelength that can expose the polyimide film. Namely, it is necessary to perform the steps in, e.g., a yellow room. Normally, the step of polishing the back surface is not carried out in the environment.

The invention provides a method for manufacturing a semiconductor device that can stably form a plated layer on a plating base layer while reducing adhered chippings.

### SUMMARY

A first aspect of the invention may comprise forming an insulating film covering at least a base metal on a diffusion region of a semiconductor substrate, forming an organic coating film having an opening at least at a surface section of the base metal being to be exposed on the insulating film, pasting a surface protection tape on the semiconductor substrate to cover the insulating film and the organic coating film, polishing a back surface of the semiconductor substrate that opposes the base metal, removing the surface protection tape, etching the insulating film with the organic coating film used as a mask to expose the base metal and forming a conductive plated layer on the base metal.

Further, another aspect of the invention may comprise forming an organic coating film having an opening at least at a surface section of a base metal being to be exposed on the base metal on a diffusion region of a semiconductor substrate, forming an insulating film on the semiconductor substrate to cover the base metal and the organic coating film, pasting a surface protection tape on the insulating film and the organic coating film, polishing a back surface of the semiconductor substrate that opposes the base metal, removing the surface protection tape and the insulating film and forming a conductive plated layer on the base metal.

Further, another aspect of the invention may comprise forming an organic coating film covering at least a base metal on a diffusion region of a semiconductor substrate patterning the organic coating film to leave the thinner organic coating film at least in the surface section of the base metal being to be exposed, pasting a surface protection tape to cover the organic coating film, polishing a back surface of the semiconductor substrate that opposes the base metal; removing the surface protection tape and removing the organic coating film on the surface section of the base metal being to be exposed; and forming a conductive plated layer on the base metal.

### DESCRIPTION OF DRAWINGS

The accompanying drawings, which are incorporated in and constitute a part of this specification, illustrate embodiments of the invention and together with the description, serve to explain the principles of the invention.

FIG. 1 is a cross sectional diagram schematically showing a semiconductor device according to a first embodiment of the invention.

FIG. 2 is a cross sectional structure diagram schematically showing a method for manufacturing the semiconductor device according to the first embodiment of the invention.

FIG. 3 is a cross sectional diagram schematically showing a semiconductor device according to a second embodiment of the invention.

FIG. 4 is a cross sectional structure diagram schematically showing a method for manufacturing the semiconductor device according to the second embodiment of the invention.

FIG. 5 is a cross sectional diagram schematically showing a semiconductor device according to a third embodiment of the invention.

FIG. 6 is a cross sectional structure diagram schematically showing a method for manufacturing the semiconductor device according to the third embodiment of the invention.

### DETAILED DESCRIPTION

Embodiments of the invention will be hereinafter described with reference to the drawings. In the drawings, the same constituent elements are attached with the same reference numerals. It should be noted that a polished back surface side of a semiconductor substrate is assumed to be a lower side, and the surface opposite thereto is assumed to be an upper side.

### First Embodiment

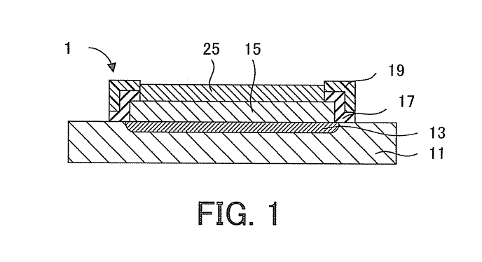

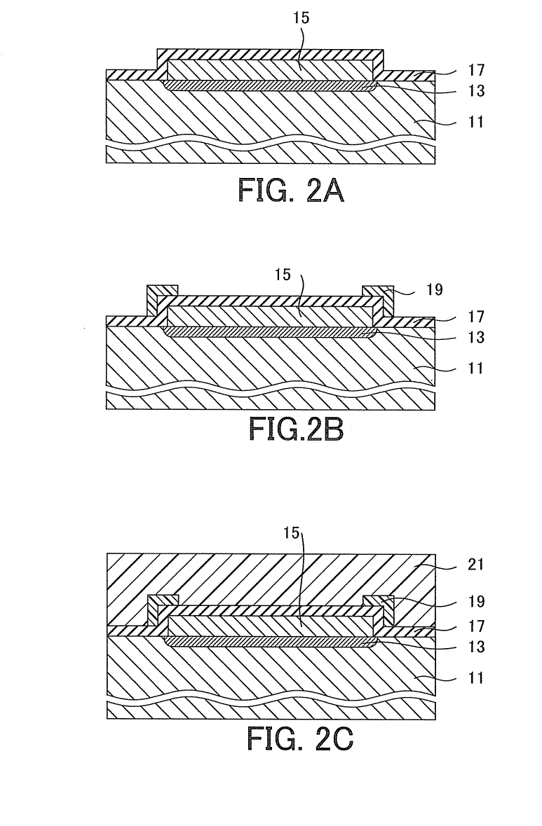

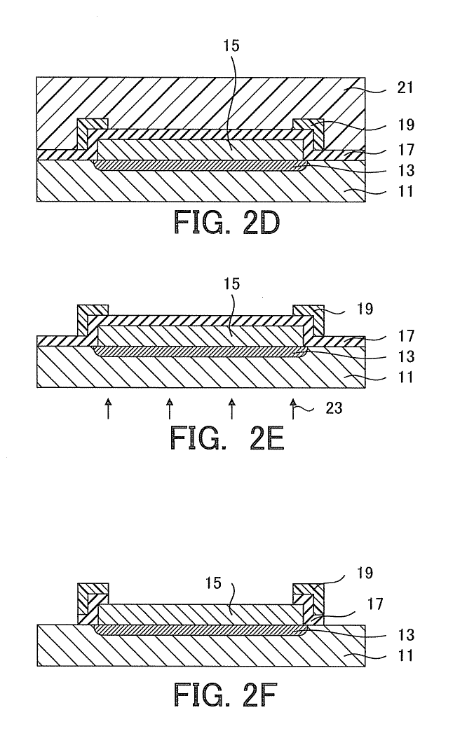

A method for manufacturing a semiconductor device according to the first embodiment of the invention will be described with reference to FIG. 1 and FIG. 2.

As shown in FIG. 1, the semiconductor device 1 includes a semiconductor substrate 11 with a back surface of which is polished. A base metal 15 and a plated layer 25 arranged on the surface of the semiconductor substrate 11. And a passivation film including an insulating film 17 and a polyimide film 19 thereon. The insulating film 17 is arranged on the surface of the semiconductor substrate 11 and on the side of the base metal 15 and the plated layer 25.

The semiconductor device 1 includes, for example, a vertical diode, i.e., a semiconductor element, in which an electric current flows between the surface and the back surface. Some sections of the semiconductor device 1 are omitted in the figure. The semiconductor device 1 has a diffusion region 13 of the semiconductor substrate 11 made of Si (silicon) to form a pn junction. The base metal 15 is arranged so as to directly connect to the diffusion region 13. And an electrode opposing the base metal 15 and the plated layer 25 is arranged on a back surface. The base metal 15 corresponds to a portion of a wiring layer or a portion of a pad electrode. The semiconductor device 1 is also formed with a lattice defect region, not shown in the figure, made in the semiconductor substrate 11 by Helium (He) irradiation, thus capable of operating at a fast rate with carrier life-time control.

The semiconductor device 1 may have a junction termination structure, not shown in the figure, under the passivation film including the insulating film 17 and the polyimide film 19 and of the semiconductor substrate 11 in order to improve pressure resistance. The junction termination structure may be constituted by, for example, a guard ring (field limiting ring) structure, a RESURF (Reduced Surface Field) structure, a field plate structure, a SIPOS (Semi-Insulating Polycrystalline Silicon) structure, a VLD (Variation of Lateral Doping) structure, and a combination thereof.

The base metal 15 is made of Al (aluminum), an alloy of Al applied with Si or Cu (copper). The plated layer 25 includes Ni (nickel) on the base metal 15 side, and Au (gold) is stacked thereon.

The insulating film 17 is formed with a silicon oxide film. Alternatively, the insulating film 17 may be a silicon nitride film. The polyimide film 19 is, for example, a non-photosensitive polyimide. The insulating film 17 and the polyimide film 19 come into close contact with the base metal 15 and the plated layer 25 so as to closely contact with the surface of the semiconductor substrate 11. The upper surface of the polyimide film 19 of the upper sidewall of the base metal 15 is at the same level as the upper surface of the plated layer 25 or at a position higher than the upper surface of the plated layer 25. The upper surface of the polyimide film 19 may be arranged at a position lower than the upper surface of the plated layer 25. A region on the surface of the semiconductor substrate 11 without the insulating film 17 and the polyimide film 19 is, for example, a region for a dicing line.

Subsequently, the method for manufacturing the semiconductor device 1 will be described. As shown in FIG. 2A, the insulating film 17 made of a silicon oxide film is formed on the semiconductor substrate 11 by Chemical Vapor Deposition (CVD) or Spin-on-Glass (SOG) methods so as to cover the base metal 15 arranged on the surface. The semiconductor substrate 11 is formed with the diffusion region 13, the surface region of which is doped with impurity in advance, so that a pn junction for a diode is formed. The base metal 15 is arranged in contact with the diffusion region 13 of the semiconductor substrate 11 so as to electrically connect therewith.

As shown in FIG. 2B, the polyimide film 19, i.e., a patterned organic coating film, is formed so as to have openings at sections in which the surface of the base metal 15 is to be exposed, sections for dicing lines, and the like. For example, the non-photosensitive polyimide film 19 is formed to cover the upper surface of the insulating film 17, and is patterned by photolithography. The polyimide film 19 is used as a mask for making openings on the insulating film 17 in subsequent steps. The polyimide film 19 serves as a sidewall for forming the plated layer 25 on the base metal 15, and functions as the passivation film for the semiconductor device 1. Here, the polyimide film 19 may have photosensitive property.

As shown in FIG. 2C, a surface protection tape 21 is pasted to cover the upper surface of the polyimide film 19 and the insulating film 17. The surface of the semiconductor substrate 11 is uneven, and therefore it is difficult to paste the surface protection tape 21 without completely any space therebetween. However, it is not so difficult to paste the surface protection tape 21 to such an extent that the semiconductor substrate 11 is protected when the back surface is polished.

As shown in FIG. 2D, the back surface of the semiconductor substrate 11 pasted with the surface protection tape 21 is thinned by a well-known back-surface polishing method. When chippings and the like are made by polishing, the back surface can be finished by a polishing equivalent to Chemical Mechanical Polish (CMP) or a wet etching method.

As shown in FIG. 2E, the surface protection tape 21 is removed from the semiconductor substrate 11. And a helium irradiation 23 is performed on the back surface side of the semiconductor substrate 11. The irradiation energy of the helium irradiation 23 is determined according to the position the semiconductor substrate 11 at which the lattice defect region is formed. After the helium irradiation 23, anneal process (thermal process) is performed at a relatively low temperature, i.e., about 400° C., in order to maintain thermal stability of the induced lattice defect.

The carrier life-time control may be performed not only by the helium irradiation 23 but also by irradiation of an electron beam and a particle beam such as H (proton, duron). The helium irradiation 23 may also be performed on the surface side of the semiconductor substrate 11. In a case where the carrier life-time control is not necessary, the method may be carried out as follows: after removing the surface protection tape 21 from the semiconductor substrate 11, it is possible to skip the steps of the helium irradiation and the anneal process, and the subsequent steps may be performed.

As shown in FIG. 2F, the insulating film 17 is etched with the polyimide film 19 used as a mask, so as to expose sections in which the surface of the base metal 15 is to be exposed and sections for dicing lines.

As shown in FIG. 1, a Ni layer of about 5 μm is plated on the exposed surface of the base metal 15 by electroless plating, and thereupon, an Au layer of about 0.1 μm is plated, so that a plated layer 25 is formed. The sidewall of the plated layer 25 is defined according to the sidewall of the insulating film 17 and the polyimide film 19. After this, or before the electroless plating, a back surface electrode layer, not shown in the figure, is formed on the back surface of the semiconductor substrate 11 so as to oppose the plated layer 25. Subsequently, the semiconductor substrate 11 and the films thereon are divided along the dicing lines into individual components. Each of the individual components is completed as the semiconductor device 1.

As described above, the method for manufacturing the semiconductor device 1 includes forming the insulating film 17 on the semiconductor substrate 11 having the diffusion region 13 in the surface region and the base metal 15 connected to the diffusion region 13 so that the insulating film 17 covers the base metal 15, forming the patterned polyimide film 19 on the insulating film 17 so that openings are arranged at least at sections in which the surface of the base metal 15 is to be exposed, pasting the surface protection tape 21 on the insulating film 17 and the polyimide film 19, polishing the back surface of the semiconductor substrate 11 opposing the base metal 15, removing the surface protection tape 21 of the semiconductor substrate 11, annealing the semiconductor substrate 11 upon performing the helium irradiation 23 for the carrier life-time control into the semiconductor substrate 11 via the insulating film 17 or the base metal 15, etching the insulating film 17 with the polyimide film 19 used as the mask and exposing the base metal 15, and forming the plated layer 25 made of Ni/Au onto the base metal 15.

As a result, the back surface of the semiconductor device 1 is polished in a state where the surface of the base metal 15 is covered by the insulating film 17. Chippings adhere to the surface of the base metal 15 much less frequently. Since the chippings hardly adhere to the base metal 15, the plated layer 25 grows on the surface of the base metal 15 without any hindrance. Further, the plated film 25 is stable in terms of the position on the surface, the shape, and the stacking state. Therefore, when, for example, the elements are implemented with soldering, wettability and conductivity of the solder are enhanced, so that the reliability of the semiconductor device 1 can be enhanced.

The surface of the base metal 15 comes into contact with the surface protection tape 21 in a state where it is covered by the insulating film 17. Therefore, it is possible to avoid carbon contamination caused by an adhesive section of the surface protection tape 21. Likewise, the surface of the base metal 15 can be protected from carbon contamination, oxidation, and the like caused by the polyimide film 19 during anneal process after the helium irradiation 23.

Further, the semiconductor device 1 is subjected to the helium irradiation 23 for the carrier life-time control, the anneal process, and then the Ni/Au plating process. Therefore, Ni diffusion to the surface is reduced after the plating. Since the surface of the plated film 25 is covered by Au, the wettability of solder is stably improved during implementation.

Further, in the semiconductor device 1, the surface protection tape 21 is pasted to the surface side during the step of polishing the back surface. Therefore, the surface protection tape 21 can provide a function for sufficiently protecting the surface. This step is simpler than substituting the polyimide film for the surface protection tape.

### Second Embodiment

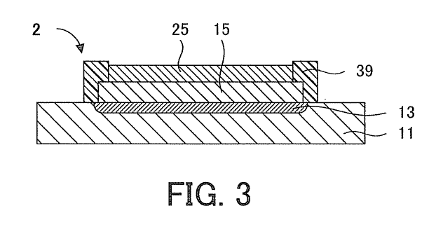

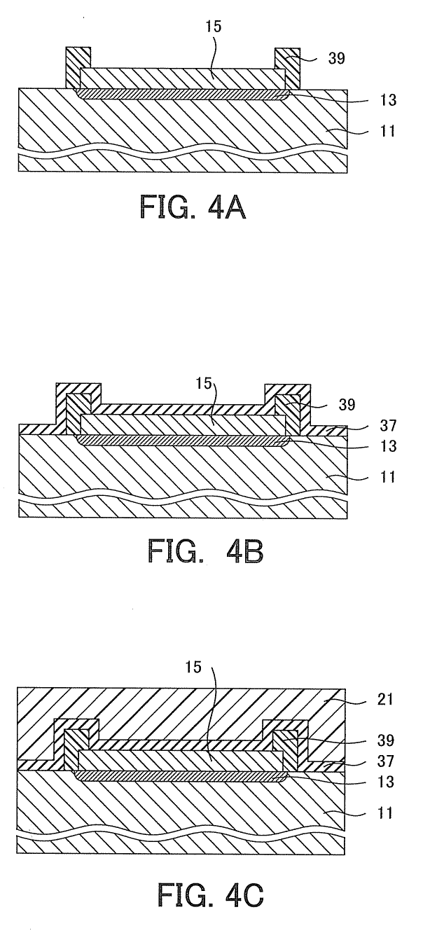

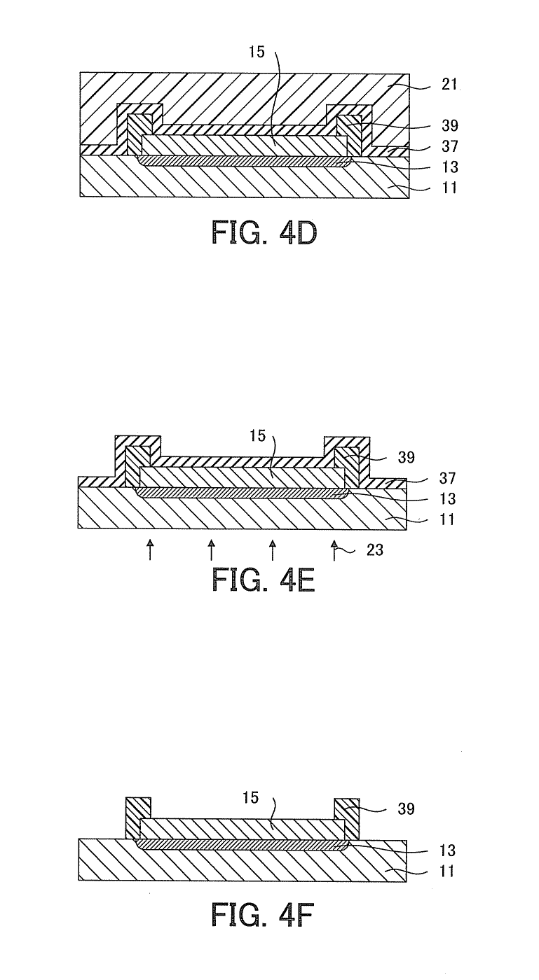

A method for manufacturing a semiconductor device according to the second embodiment of the invention will be described with reference to FIG. 3 and FIG. 4. This embodiment is different from the semiconductor device 1 according to the first embodiment in that the passivation film is a single layer polyimide film. The same constituent elements as those of the first embodiment are attached with the same reference numerals, and the description thereof is omitted.

As shown in FIG. 3, a semiconductor device 2 as well as the semiconductor device 1 includes the semiconductor substrate 11, the base metal 15, and the plated layer 25. Further, the semiconductor device 2 includes a polyimide film 39 arranged on the surface of the semiconductor substrate 11 and on the side of the base metal 15 and the plated layer 25. The polyimide film 39 as well as the polyimide film 19 is, for example, a non-photosensitive polyimide.

Subsequently, the method for manufacturing the semiconductor device 2 will be described. As shown in FIG. 4A, the polyimide film 39, which is a patterned organic coating film, is formed so as to have openings at sections in which the surface of the base metal 15 is to be exposed, sections for dicing lines, and the like. For example, the non-photosensitive polyimide film 39 is formed to cover the upper surface of the base metal 15 and the semiconductor substrate 11, and is patterned by photolithography. The polyimide film 39 serves as a sidewall for forming the plated layer 25 on the base metal 15 in the later step, and further functions as the passivation film for the semiconductor device 2.

As shown in FIG. 4B, an insulating film 37 made of a silicon oxide film is formed on the semiconductor substrate 11 by Chemical Vapor Deposition (CVD) or Spin-on-Glass (SOG) methods so as to cover the base metal 15 and the polyimide film 39.

As shown in FIG. 4C, the surface protection tape 21 is pasted to cover the upper surface of the insulating film 37.

As shown in FIG. 4D, the back surface of the semiconductor substrate 11 pasted with the surface protection tape 21 is thinned by a well-known back-surface polishing method.

As shown in FIG. 4E, the surface protection tape 21 is removed. Then, the helium irradiation 23 is performed on the back surface side of the semiconductor substrate 11. After the helium irradiation 23, anneal process (thermal process) is performed at about 400° C.

As shown in FIG. 4F, the insulating film 37 is etched, so as to expose sections in which the surface of the base metal 15 is to be exposed, the polyimide film 39, and dicing line sections of the semiconductor substrate 11.

As shown in FIG. 3, a Ni layer of about 5 μm is plated on the exposed surface of the base metal 15 by electroless plating, and thereupon, an Au layer of about 0.1 μm is plated, so that the plated layer 25 is formed. Thereafter, the same steps as those in the method for manufacturing the semiconductor device according to the first embodiment are carried out, and as a result, the semiconductor device 2 is completed.

In the semiconductor device 2, for example, the surface of the base metal 15 is covered by the insulating film 37. Alternatively, a polyimide film may be used instead of the insulating film 37. For example, the polyimide film is removed by ashing method until the surface of the base metal 15 is exposed right before the plated layer 25 is formed.

As described above, in the semiconductor device 2, the single layer polyimide film 39 is used as the passivation film. The insulating film of the semiconductor device 1 according to the first embodiment is constituted by a stacked structure including the insulating film 17 and the polyimide film 19. In contrast, the insulating film of the semiconductor device 2 is the single layer polyimide film 39. Therefore, the passivation film of the semiconductor device 2 does not include any interface between different types of films, and can reduce peeling off and abnormal etching occurring at the interface, thus achieving a higher reliability. In addition, the semiconductor device 2 has the same effects as those of the semiconductor device 1.

### Third Embodiment

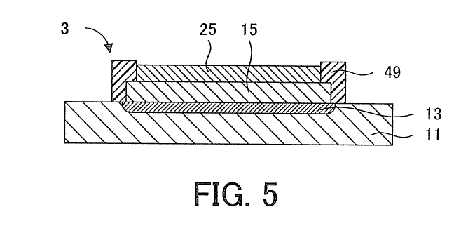

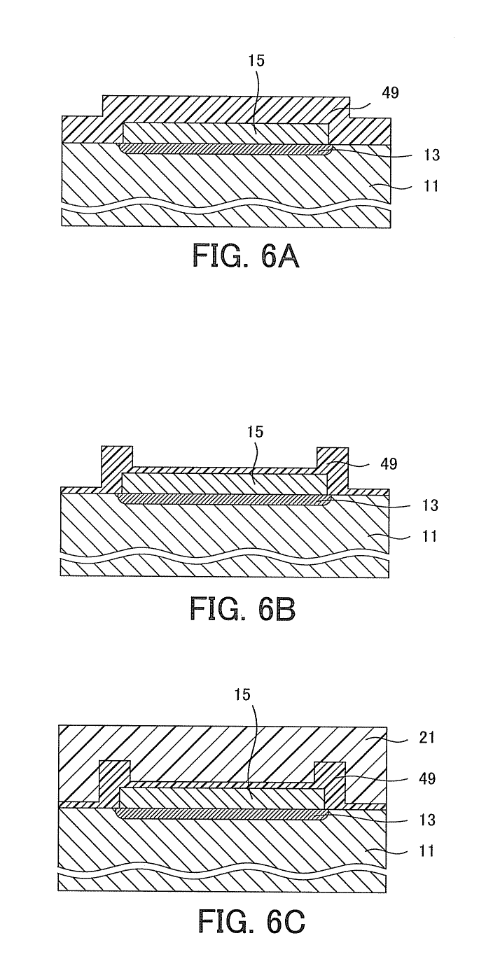

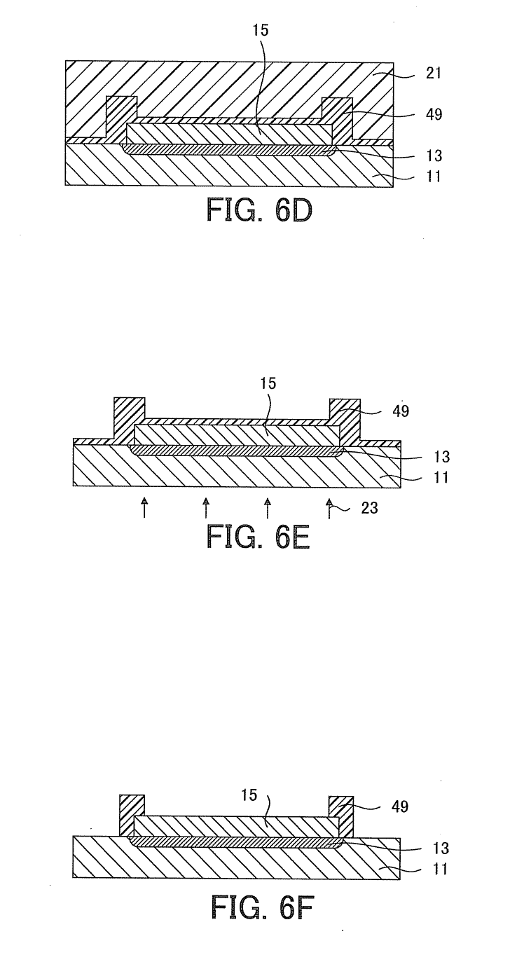

A method for manufacturing a semiconductor device according to the third embodiment of the invention will be described with reference to FIG. 5 and FIG. 6. This embodiment is different from the semiconductor device 1 according to the first embodiment in that the passivation film is a single layer polyimide film. This embodiment is different from the method for manufacturing the semiconductor device 2 according to the second embodiment in that the insulating film is not necessary. The same constituent elements as those of the first and second embodiments are attached with the same reference numerals, and the description thereof is omitted.

As shown in FIG. 5, the semiconductor device 3 has the same configuration as that of the semiconductor device 2, and has a polyimide film 49 which is manufactured by a different method. The polyimide film 49 is, for example, non-photosensitive.

Subsequently, the method for manufacturing the semiconductor device 3 will be described. As shown in FIG. 6A, the non-photosensitive polyimide film 49, which is an organic coating film, is formed on the semiconductor substrate 11 and the base metal 15.

As shown in FIG. 6B, the polyimide film 49 is patterned so that the polyimide film 49 has a thin film thickness in the sections in which the surface of the base metal 15 is to be exposed and in the sections for dicing lines. The polyimide film 49 is patterned so that the polyimide film 49 is left as a thick film in the side section of the base metal 15 that is to be left as the passivation film. In other words, a photoresist (not shown in the figure) patterned on the polyimide film 49 is formed by photolithography. And the polyimide film 49 is etched with the photoresist used as the mask. The polyimide film 49 remains as a thin film, for example, remains a thin film having a thickness half the original thickness.

As shown in FIG. 6C, the surface protection tape 21 is pasted to cover the upper surface of the polyimide film 49.

As shown in FIG. 6D, the back surface of the semiconductor substrate 11 pasted with the surface protection tape 21 is thinned by a well-known back-surface polishing method.

As shown in FIG. 6E, the surface protection tape 21 is removed. Then, the helium irradiation 23 is performed on the back surface side of the semiconductor substrate 11. After the helium irradiation 23, anneal process (thermal process) is performed at about 400° C.

As shown in FIG. 6F, the polyimide film 49 is etched, so as to expose sections in which the surface of the base metal 15 is to be exposed and dicing line sections of the semiconductor substrate 11. For example, the polyimide film 49 is subjected to ashing by ashing method until the sections in which the surface of the base metal 15 is to be exposed and the semiconductor substrate 11 are exposed. The original film thickness of the sections of the polyimide film 49 that are left as the passivation film is determined. The film thickness attains an appropriate thickness when the ashing is finished.

As shown in FIG. 5, a Ni layer of about 5 μm is plated on the exposed surface of the base metal 15 by electroless plating. And an Au layer of about 0.1 μm is plated on the Ni layer. The plated layer 25 is formed. Thereafter, the same steps as those in the method for manufacturing the semiconductor devices according to the first and second embodiments are carried out. As a result, the semiconductor device 3 is completed.

As described above, the semiconductor device 3 has the single layer polyimide film 49 as the passivation film, and therefore has the same configuration as the semiconductor device 2. In other words, the semiconductor device 3 has the same effects as those of the semiconductor device 2. Further, in contrast to the semiconductor device 2, the semiconductor device 3 can be made by simpler manufacturing process, as the semiconductor device 3 does not need the insulating film 37.

As described above, the invention can provide a method for manufacturing a semiconductor device that can stably form the plated layer on the plating base layer while reducing adhered chippings.

The invention is not limited to the above embodiments, and can be embodied as various kinds of modifications without deviating from the gist of the invention.

In the above embodiments, the semiconductor device includes a diode. Alternatively, for example, the semiconductor device may include other types of semiconductor elements, such as a discrete element such as diodes including SBD (Schottky Barrier Diode), MOSFET (Metal Oxide Semiconductor Field Effect Transistor), and IGBT (Insulated Gate Bipolar Transistor), a logic LSI, a memory, or the like.

In the above embodiments, the method for manufacturing the semiconductor device includes the helium irradiation step. However, some diodes do not require the carrier life-time control. In this case, the above embodiments can be applied without the helium irradiation step. The method for manufacturing the semiconductor device without the helium irradiation step can be used as not only the method for manufacturing the semiconductor device having the diode but also the method for manufacturing semiconductor devices having various kinds of semiconductor elements.

In the above embodiments, the plated layer is Ni/Au. Alternatively, the plated layer may be a single layer or stacked layers that are made of various kinds of conductive materials such as Ni, Au, Pd, Sn, Cr, Cu, and Ag, in accordance with the mode of implementation, the connection method, and the like of the semiconductor device.

In the above embodiments, Si is used in the semiconductor substrate. Alternatively, the semiconductor substrate may be made of a compound semiconductor such as SiC (Silicon Carbide), GaN (Gallium Nitride), and GaA (Gallium Arsenide), and a wide band gap semiconductor such as a diamond.

What is claimed is:

1. A method for manufacturing a semiconductor device comprising:
forming an insulating film covering at least a base metal on a diffusion region of a semiconductor substrate;
forming an organic coating film having an opening at least at a surface section of the base metal being to be exposed on the insulating film;
pasting a surface protection tape on the semiconductor substrate to cover the insulating film and the organic coating film;
polishing a back surface of the semiconductor substrate that opposes the base metal;
removing the surface protection tape;
etching the insulating film with the organic coating film used as a mask to expose the base metal; and
forming a conductive plated layer on the base metal.

2. A method for manufacturing a semiconductor device comprising:
forming an organic coating film having an opening at least at a surface section of a base metal being to be exposed on the base metal on a diffusion region of a semiconductor substrate;
forming an insulating film on the semiconductor substrate to cover the base metal and the organic coating film;
pasting a surface protection tape on the insulating film and the organic coating film;
polishing a back surface of the semiconductor substrate that opposes the base metal; removing the surface protection tape and the insulating film; and
forming a conductive plated layer on the base metal.

3. A method for manufacturing a semiconductor device comprising:
forming an organic coating film covering at least a base metal on a diffusion region of a semiconductor substrate patterning the organic coating film to leave the thinner organic coating film at least in the surface section of the base metal being to be exposed;
pasting a surface protection tape to cover the organic coating film;
polishing a back surface of the semiconductor substrate that opposes the base metal;
removing the surface protection tape and removing the organic coating film on the surface section of the base metal being to be exposed; and
forming a conductive plated layer on the base metal.

4. The method for manufacturing the semiconductor device according to claim 1, further comprising annealing the semiconductor substrate upon irradiating particles for carrier life-time control into the semiconductor substrate from the back surface side opposing the base metal of the semiconductor substrate after the surface protection tape of the semiconductor substrate is removed.

5. The method for manufacturing the semiconductor device according to claim 1, wherein the organic coating film is a polyimide film.

6. The method for manufacturing the semiconductor device according to claim 1, wherein the base metal is an aluminum or a metal including an aluminum.

7. The method for manufacturing the semiconductor device according to claim 1, wherein the plated layer is made of a nickel and a gold.

8. The method for manufacturing the semiconductor device according to claim 1, wherein the insulating film is a silicon oxide film or a silicon nitride film formed according to any one of CVD method and Spin-on-Glass method.

9. The method for manufacturing the semiconductor device according to claim 2, further comprising annealing the semiconductor substrate upon irradiating particles for carrier life-time control into the semiconductor substrate from the back surface side opposing the base metal of the semiconductor substrate after the surface protection tape of the semiconductor substrate is removed.

10. The method for manufacturing the semiconductor device according to claim 2, wherein the organic coating film is a polyimide film.

11. The method for manufacturing the semiconductor device according to claim 2, wherein the base metal is an aluminum or a metal including an aluminum.

12. The method for manufacturing the semiconductor device according to claim 2, wherein the plated layer is made of a nickel and a gold.

13. The method for manufacturing the semiconductor device according to claim 2, wherein the insulating film is a silicon oxide film or a silicon nitride film formed according to any one of CVD method and Spin-on-Glass method.

14. The method for manufacturing the semiconductor device according to claim 3, further comprising annealing the semiconductor substrate upon irradiating particles for carrier life-time control into the semiconductor substrate from the back surface side opposing the base metal of the semiconductor substrate after the surface protection tape of the semiconductor substrate is removed.

15. The method for manufacturing the semiconductor device according to claim 3, wherein the organic coating film is a polyimide film.

16. The method for manufacturing the semiconductor device according to claim 3, wherein the base metal is an aluminum or a metal including an aluminum.

17. The method for manufacturing the semiconductor device according to claim 3, wherein the plated layer is made of a nickel and a gold.

18. The method for manufacturing the semiconductor device according to claim 3, wherein the insulating film is a silicon oxide film or a silicon nitride film formed according to any one of CVD method and Spin-on-Glass method.
